(19) United States
(12) Patent Application Publication
(10) Pub. No.: US 2008/0143450 A1
(43) Pub. Date: Jun. 19, 2008

(54) PIEZOELECTRIC OSCILLATOR AND METHOD FOR MANUFACTURING THE SAME, AND MEMS DEVICE AND METHOD FOR MANUFACTURING THE SAME

(75) Inventors: Akihito MATSUMOTO, Chino (JP); Takamitsu HIGUCHI, Matsumoto (JP); Akio KONISHI, Shiojiri (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/957,592

(22) Filed: Dec. 17, 2007

(30) Foreign Application Priority Data
Dec. 18, 2006 (JP) 2006-339867

(51) Int. Cl. H03B 5/36; H01L 41/08; H01L 41/047; H01L 41/107; H01L 41/22

(52) U.S. Cl. 331/116 R; 310/318; 310/370; 29/25.35

(57) ABSTRACT

A piezoelectric oscillator includes: a base substrate; a frame-like supporting section formed from a portion of the base substrate; and a plurality of oscillator sections, wherein each of the oscillator sections includes an oscillation section that is formed from a portion of the base substrate, and has one end affixed to an inner side of the support section and another free end, and a driving section that generates flexing vibration at the oscillation section, and wherein the oscillation sections are different in length, and each of the driving sections has a first electrode formed above the base substrate, a piezoelectric layer formed above the first electrode, and a second electrode formed above the piezoelectric layer.

The entire disclosure of Japanese Patent Application No. 2006-339867, filed Dec. 18, 2006 is expressly incorporated by reference herein.

### BACKGROUND

1. Technical Field

The present invention relates to piezoelectric oscillators and methods for manufacturing the same, and MEMS devices and methods for manufacturing the same.

2. Related Art

Piezoelectric oscillators are generally used in oscillator sections of clock modules in information apparatuses such as clocks and microcomputers. A driving method using the piezoelectric effect is widely used in piezoelectric oscillators. Recently, a piezoelectric oscillator provided with a driver section in which a piezoelectric thin film is sandwiched between upper and lower electrodes on a silicon substrate has been developed. Japanese Laid-open Patent Application JP-A-2005-249395 is an example of related art.

### SUMMARY

In accordance with an advantage of some aspects of the invention, a piezoelectric oscillator that can output singles with a variety of frequencies and a method for manufacturing the same are provided. Also, in accordance with another advantage of the aspects of the invention, a MEMS device equipped with the piezoelectric oscillator and a method for manufacturing the same are provided.

A piezoelectric oscillator in accordance with an embodiment of the invention includes: a base substrate; a frame-like supporting section formed from a portion of the base substrate; and a plurality of oscillator sections, wherein each of the oscillator sections includes an oscillation section that is formed from a portion of the base substrate, and has one end affixed to an inner side of the support section and another free end, and a driving section that generates flexing vibration at the oscillation section, and wherein the oscillation sections are different in length, and each of the driving sections has a first electrode formed above the base substrate, a piezoelectric layer formed above the first electrode, and a second electrode formed above the piezoelectric layer.

The piezoelectric oscillator in accordance with the present embodiment of the invention includes the plurality of oscillator sections, wherein the oscillator sections are equipped with the oscillation sections that are different in length, respectively. Because the oscillation sections have different lengths, the resonance frequency of the flexing vibration of each of the oscillation sections is different from one another. Accordingly, by combining on/off operations of the oscillation sections, signals with a variety of frequencies can be outputted from the single piezoelectric oscillator.

It is noted that, in the descriptions concerning the invention, the term “above” may be used, for example, as “a specific element (hereafter referred to as “A”) is formed ‘above’ another specific element (hereafter referred to as “B”).” In this case, the term “above” is assumed to include a case in which A is formed directly on B, and a case in which A is formed above B through another element.

In the piezoelectric oscillator in accordance with an aspect of the present embodiment of the invention, each of the oscillation sections may be formed from a single beam section, and each of the oscillation sections is provided on each one of the beam sections.

In the piezoelectric oscillator in accordance with an aspect of the present embodiment of the invention, each of the oscillation sections may have a tuning fork shape composed of a base section and two beam sections with the base section as a base end, and each of the beam sections may be provided with a pair of the driving sections.

In the piezoelectric oscillator in accordance with an aspect of the present embodiment of the invention, the free ends of at least a portion of the plurality of oscillation sections may be disposed opposite to each other.

In the piezoelectric oscillator in accordance with an aspect of the present embodiment of the invention, at least two areas in a plan view among areas between opposing free ends are equal to each other.

A MEMS (Micro Electro Mechanical System) device in accordance with an embodiment of the invention includes the piezoelectric oscillator described above, and a control circuit that feeds back an output of the piezoelectric oscillator and controls a frequency of the output.

A method for manufacturing a MEMS device in accordance with an embodiment of the invention includes the steps of: forming a MEMS wafer having the piezoelectric oscillator described above, and a control circuit that feeds back an output of the piezoelectric oscillator and controls a frequency of the output; and operating the piezoelectric oscillator and the control circuit on the MEMS wafer to measure a frequency of an output of the piezoelectric oscillator.

A method for manufacturing a piezoelectric oscillator in accordance with an embodiment of the invention includes the steps of:

preparing a base substrate having a substrate, a first layer formed above the base substrate and a second layer formed above the first layer;

forming, above the base substrate, a driving section that generates flexing vibration of an oscillation section of each of a plurality of oscillator sections;

patterning the second layer to form a frame-like supporting section, the oscillation section having a base end at an inner side of the supporting section and another end provided so as not to contact the supporting section, a connecting section that connects the oscillation sections together, and an opening section that exposes the first layer;

removing a portion of the first layer exposed through the opening section by wet etching, thereby forming a cavity section at least below the oscillation section; and

removing the connecting section by dry etching after forming the cavity section,

wherein the step of forming the driving section includes the steps of forming a first electrode above the base substrate, forming a piezoelectric layer above the first electrode, and forming a second electrode above the piezoelectric layer, wherein the oscillation sections are formed in different lengths, free ends of at least a portion of the plurality of oscillation sections are disposed opposite to each other, the connection section is provided between the opposing free ends, and at least two of the connection sections are formed to have the same area in a plan view.

### BRIEF DESCRIPTION OF THE DRAWINGS

FIG. 1 is a plan view schematically showing a piezoelectric oscillator in accordance with an embodiment of the invention.

FIG. 2 is a cross-sectional view schematically showing the piezoelectric oscillator in accordance with the embodiment of the invention.

FIG. 3 is a cross-sectional view schematically showing a step of manufacturing a piezoelectric oscillator in accordance with an embodiment of the invention.

FIG. 4 is a cross-sectional view schematically showing a step of manufacturing the piezoelectric oscillator in accordance with the present embodiment.

FIG. 5 is a cross-sectional view schematically showing a step of manufacturing the piezoelectric oscillator in accordance with the present embodiment.

FIG. 6 is a cross-sectional view schematically showing a step of manufacturing the piezoelectric oscillator in accordance with the present; embodiment.

FIG. 7 is a cross-sectional view schematically showing a step of manufacturing the piezoelectric oscillator in accordance with the present embodiment.

FIG. 8 is a circuit diagram schematically showing a MEMS device in accordance with an embodiment of the invention.

FIG. 9 is a flow chart of execution of signal processing by the MEMS device in accordance with the present embodiment.

FIG. 10 is plan view schematically showing a step of manufacturing a MEMS device in accordance with an embodiment of the invention.

FIG. 11 is a plan view schematically showing a piezoelectric oscillator in accordance with a modified example of the embodiment of the invention.

FIG. 12 is a plan view schematically showing a piezoelectric oscillator in accordance with a modified example of the embodiment of the invention.

FIG. 13 is a cross-sectional view schematically showing a piezoelectric oscillator in accordance with a modified example of the embodiment of the invention.

### DESCRIPTION OF EXEMPLARY EMBODIMENTS

Preferred embodiments of the invention are described below with reference to the accompanying drawings.

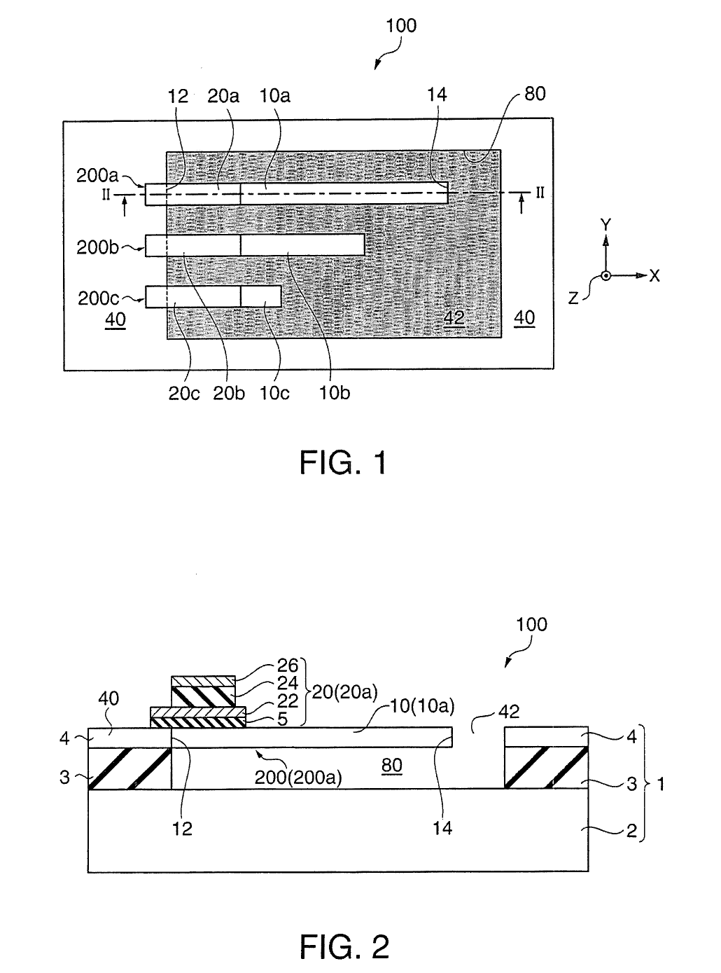

1. First, a piezoelectric oscillator 100 in accordance with an embodiment of the invention is described. FIG. 1 is a plan view schematically showing the piezoelectric oscillator 100 in accordance with the present embodiment, and FIG. 2 is a cross-sectional view schematically showing the piezoelectric oscillator 100. It is noted that FIG. 2 is a cross-sectional view taken along a line II-II in FIG. 1.

The piezoelectric oscillator 10 includes a base substrate 1, a supporting section 40 and an oscillator section 200, as shown in FIG. 1 and FIG. 2.

For example, as shown in FIG. 2, the base substrate 1 has a substrate 2, a first layer 3 formed on the substrate 2, and a second layer 4 formed on the first layer 3. The first layer 3 may be, for example, a dielectric layer, and the second layer 4 may be, for example, a semiconductor layer. As the base substrate 1, for example, a SOI (Silicon On Insulator) substrate may be used. For example, a silicon substrate may be used as the substrate 2, a silicon oxide layer as the first layer (hereafter also referred to as a “dielectric layer”) 3, and a silicon layer as the second layer (hereafter also referred to as a “semiconductor layer”) 4. A variety of kinds of semiconductor circuits can be formed in the semiconductor layer 4. The use of a silicon layer as the semiconductor layer 4 may be advantageous because an ordinary semiconductor manufacturing technology can be used. The dielectric layer 3 has a thickness of, for example, 2 μm-4 μm, and the semiconductor layer 4 has a thickness of, for example, 4 μm-20 μm.

The supporting section 40 is formed from a portion of the base substrate 1. The supporting section 40 is formed from, for example, as shown in the figure, the semiconductor layer 4. The supporting section 40 can support the oscillation sections 10. The supporting section 40 is in a frame shape, and may be in a rectangular shaped frame (including a square shaped frame), for example, as shown in the figure.

The oscillator section 200 may include a plurality oscillator sections. As illustrated in the figure, for example, the oscillator section 200 may be provided with three oscillator section (a first oscillator section 200a, a second oscillator section 200b and a third oscillator section 200c). Each of the oscillator sections 200a, 200b and 200c has an oscillation section 10 and a driving section 20. More specifically, the first oscillator section 200a includes a first oscillation section 10a and a first driving section 20a. The second oscillator section 200b includes a second oscillation section 10b and a second driving section 20b. The third oscillator section 200c includes a third oscillation section 10c and a third driving section 20c. It is noted that the number of oscillator sections 200 is not limited to three shown in the figure.

The oscillation section 10 is formed from a portion of the base substrate 1. For example, as shown in the figure, the oscillation section 10 may be formed from a portion of the semiconductor layer 4. One end of each of the oscillation sections 10a, 10b and 10c is affixed to an inner side of the supporting section 40, and the other end is a free end. Each of the oscillation sections 10a, 10b and 10c is formed from a single beam section, for example, as shown in the figure. Each of the oscillation sections 10a, 10b and 10c may have a plane configuration that is, for example, rectangular, and is in an oblong shape in the illustrated example.

The oscillation sections 10a, 10b and 10c have different lengths, as shown in FIG. 1. For example, the first oscillation section 10a, the second oscillation section 10b and the oscillation section 10c become shorter in length in this order. It is noted that, in the present invention, the length of the oscillation section is a distance from the affixed end 12 to the free end 14 in a plan view. Also, a distance between two ends of the oscillation section in a direction (Y direction) perpendicular to a lengthwise direction (X direction) of the oscillation section is called a width of the oscillation section.

The oscillation section 10 is formed over a cavity section 80 that is formed by removing a portion of the dielectric layer 3 of the base substrate 1, as shown in FIG. 2. The cavity section 80 has a plane configuration that is, for example, rectangular, and in the illustrated example is in an oblong shape, and its longer-side direction is in the same direction as the lengthwise direction (X direction) of the oscillation section 10. An opening section 42 that allows vibration of the oscillation section 10 is formed around the oscillation section 10. The opening section 42 and the oscillation section 10, when viewed as one body in a plan view (FIG. 1), coincide with, for example, the cavity section 80.

The driving section 20 generates flexing vibration of the oscillation section 10. Each one of the driving sections 20a, 20b and 20c is provided on each one of the beam sections. Each of the driving sections 20a, 20b and 20c has a plane configuration that is, for example, rectangular, and in the illustrated example is in an oblong shape, and its longer-side direction is in the same direction as the lengthwise direction (X direction) of the oscillation section 10. Each of the driving sections 20a, 20b and 20c has, as shown in FIG. 2, a first electrode 22 formed above the base substrate 1 (more specifically, the semiconductor layer 4), a piezoelectric layer 24 formed on the first electrode 22, and a second electrode 26 formed on the piezoelectric layer 24. Each of the driving sections 20a, 20b and 20c may further have a base layer 5 formed between the semiconductor layer 4 and the first electrode 22. The major portion of the driving section 20 is formed on the oscillation section 10 on the affixed end side thereof, for example, as shown in FIG. 1 and FIG. 2. A portion of the driving section 20 (more specifically, the base layer 5 and the first electrode 22) is also formed, for example, on the supporting section 40.

The base layer 5 is a dielectric layer, such as, a silicon oxide (SiO₂) layer, a silicon nitride (Si₃N₄) layer or the like. The base layer 5 may be formed from a compound layer of, for example, 2 or more layers. The base layer 5 has a thickness of, for example, 1 μm.

The first electrode 22 may be composed of an electrode material such as Pt. The first electrode 22 may have any thickness as long as it provides a sufficiently low electrical resistance value, and may be, for example, 10 nm or more but 5 μm or less.

The piezoelectric layer 24 may be formed from piezoelectric material, such as, for example, lead zirconate titanate (Pb (Zr, Ti) O₃ PZT), lead zirconate titanate niobate (Pb (Zr, Ti, Nb) O₃: PZTN) and the like. The thickness of the piezoelectric layer 24 may be, for example, 0.1 μm-20 μm.

The second electrode 26 may be composed of an electrode material, such as, for example, Pt. The second electrode 26 may have any thickness as long as it provides a sufficiently low electrical resistance value, and may be, for example, 10 nm or more but 5 μm or less.

It is noted that, in the illustrated example, the driving section 20 has only the piezoelectric layer 24 provided between the first electrode 22 and the second electrode 26, but may have layers other than the piezoelectric layer 24 between the electrodes 22 and 26. The film thickness of the piezoelectric layer 24 can be appropriately changed according to resonance conditions.

In the piezoelectric oscillator 100 in accordance with the present embodiment, electric fields in alternately opposing directions are applied to each of the driving sections 20a, 20b and 20c, thereby causing flexing vibration at the oscillation sections 10a, 10b and, 10c in up and down directions (Z direction).

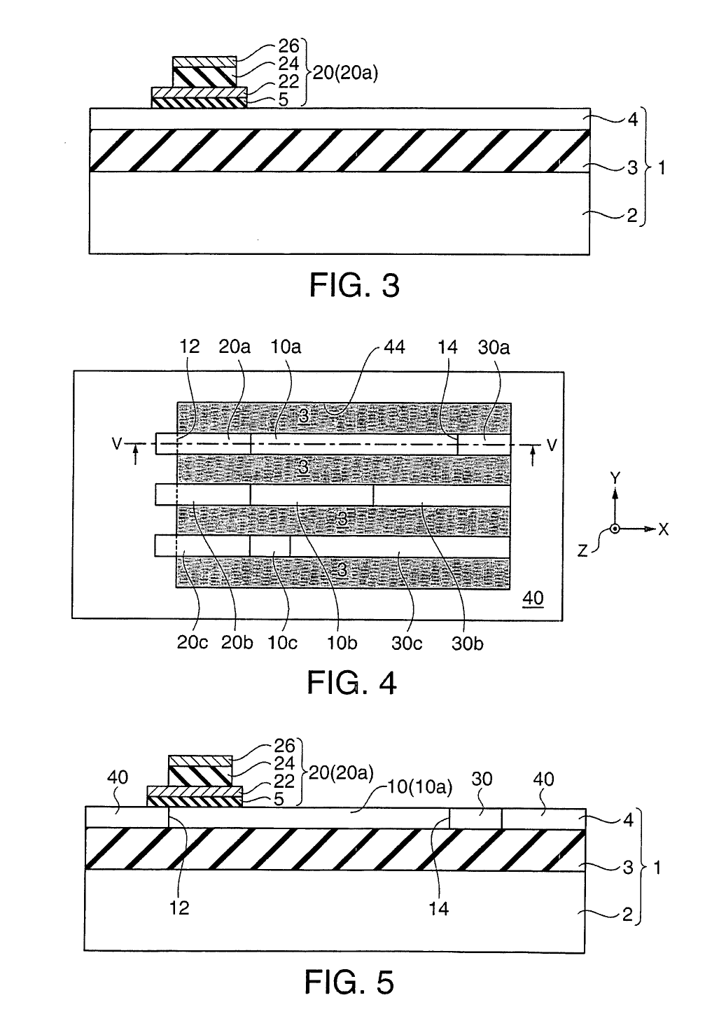

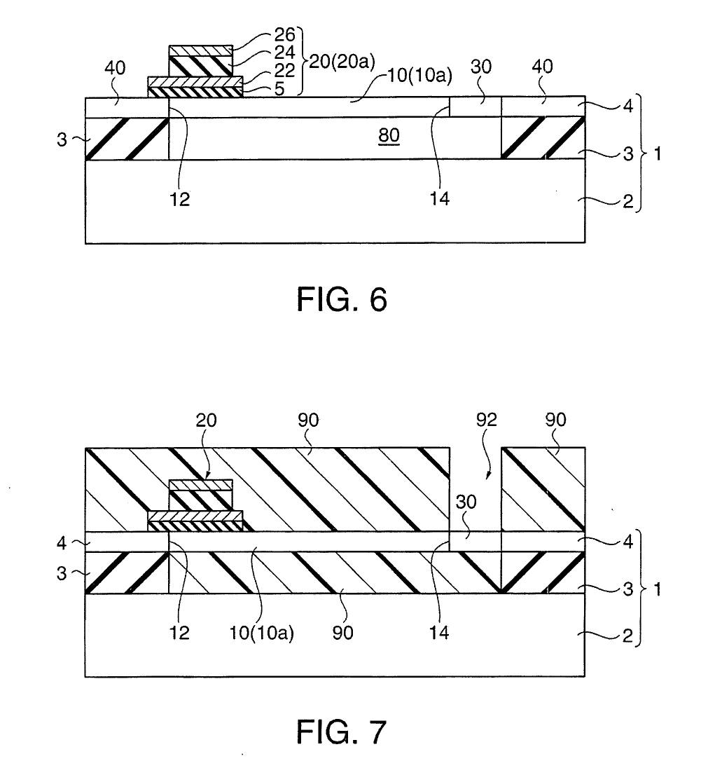

2. Next, an example of a method for manufacturing the piezoelectric oscillator 100 in accordance with an embodiment of the invention is described with reference to the accompanying drawings. FIG. 3 and FIGS. 5-7 are cross-sectional views schematically showing a manufacturing process for manufacturing the piezoelectric oscillator 100 in accordance with the present embodiment, and FIG. 4 is a plan view schematically showing the manufacturing process for manufacturing the piezoelectric oscillator 100. It is noted that FIG. 3, FIG. 6 and FIG. 7 correspond to the cross-sectional view in FIG. 2, and FIG. 5 is a cross-sectional view taken along a line V-V of FIG. 4.

(1) First, as shown in FIG. 3, a base substrate 1 having a dielectric layer 3 and a semiconductor layer 4 disposed in this order on a substrate 2 is prepared.

(2) Next, a driving section 20 is formed on the base substrate 1. More specifically, a base layer 5, a first electrode 22, a piezoelectric layer 24 and a second electrode 26 that form the driving section 20 are sequentially formed on the base substrate 1.

The base layer 5 is formed by a thermal oxidation, a CVD method or a sputter method. The base layer 5 may be patterned by using, for example, photolithography technique and etching technique, thereby being formed into a desired configuration.

The first electrode 22 is formed by a vapor deposition method, a sputter method or a plating method. The first electrode 22 may be patterned by using, for example, photolithography technique and etching technique, and is thereby formed into a desired configuration.

The piezoelectric layer 24 may be formed by a laser ablation method, a vapor deposition method, a sputter method, a CVD (Chemical Vapor Deposition) method, a solution method (sol-gel method) or the like. For example, when the piezoelectric layer 24 composed of lead zirconate titanate (PZT) is formed by a laser ablation method, a laser beam is irradiated to a PZT target, for example, a target of Pb_{1.05}Zr_{0.52}Ti_{0.48}O₃, whereby lead atoms, zirconium atoms, titanium atoms and oxygen atoms are discharged by ablation from the target, a plume is generated by laser energy, and the plume is irradiated toward the base substrate 1. As a result, the piezoelectric layer 24 composed of PZT is formed on the first electrode layer 22. The piezoelectric layer 24 is patterned by, for example, photolithography technique and etching technique, and is thereby formed into a desired configuration.

The second electrode 26 is formed by a vapor deposition method, a sputter method or a CVD method. The second electrode 26 may be patterned by, for example, photolithography technique and etching technique, and is thereby formed into a desired configuration.

(3) Next, as shown in FIG. 4 and FIG. 5, the semiconductor layer 4 of the base substrate 1 is patterned in a desired configuration, whereby a supporting section 40, a plurality of oscillation sections 10, connection sections 30 and a first opening section 44 are formed. The supporting section 40, the oscillation sections 10 and the connection sections 30 may be obtained by forming the first opening section 44 by which the semiconductor layer 44 is cut through and the dielectric layer 3 is exposed. Each of the oscillation sections 10a, 10b and 10c is provided in a manner to have a base end 12 at an inner side of the supporting section 40, and another end provided in a manner not to contact the supporting section 40. The connection section 30 may only require to be provided, for example, in a manner that the supporting section 40 and the oscillation section 10 are continuous, and the cavity section 80 is formed at a desired position in a wet etching step to be applied to the dielectric layer 3, which is described below. More specifically, for example, as shown in FIG. 4 and FIG. 5, the first connection section 30a is provided in a manner that the end (free end) 14 of the first oscillation section 10a and the supporting section 40 are continuous along the lengthwise direction (X direction). Also, the second connection section 30b is provided in a manner that the end (free end) of the second oscillation section 10b and the supporting section 40 are continuous along the lengthwise direction (X direction). Also, the third connection section 30c is provided in a manner that the end (free end) of the third oscillation section 10c and the supporting section 40 are continuous along the lengthwise direction (X direction).

The oscillation sections 10a, 10b and 10c are different in length form one another, and therefore the lengths of the connection sections 30a, 30b and 30c in the lengthwise direction (X direction) are different from one another. As shown in the figure, when the first oscillation section 10a, the second oscillation section 10b and the third oscillation section 10c become sequentially shorter in length, for example, the first connection section 30a, the second connection section 30b and the third connection section 30c may be made sequentially longer in length. The oscillation sections 10a, 10b and 10c and their respective opposing connection sections 30a, 30b and 30c are each formed in one body in a rectangular plane configuration, as shown in FIG. 4. The width of each of the oscillation sections 10 and the width of each of the connection sections 30 may be equal to each other, for example, as shown in FIG. 4.

The semiconductor layer 4 may be patterned by photolithography technique and etching technique. As the etching technique, a dry etching method or a wet etching method may be used. In this patterning step, the dielectric layer 3 of the base substrate 1 may be used as an etching stopper layer. In other words, when etching the semiconductor layer 4, the etching rate of the dielectric layer (first layer) 3 is lower than the etching rate of the semiconductor layer (second layer) 4.

(4) Next, the dielectric layer 3 of the base substrate 1 is etched by wet etching through the exposed portion at the first opening section 44, thereby forming the cavity section 80 at least below the oscillation sections 10, as shown in FIG. 6. The cavity section 80 is formed in a manner that the oscillation sections 10 can have flexing vibration in a state in which the connection sections 30 are removed (the removal of the connection sections 30 shall be described below). The cavity section 80 is formed, for example, below the oscillation sections 10, the connection sections 30 and the first opening section 44. When the dielectric layer 3 is composed of silicon oxide, the dielectric layer 3 can be removed by wet etching, using, for example, hydrofluoric acid. In the present step, for example, by using the substrate 2 and the semiconductor layer 4 as an etching stopper layer, the dielectric layer 3 can be etched by wet etching without using photolithography technique. In other words, when the dielectric layer 3 is etched, the etching rate of the semiconductor layer (second layer) 4 is lower than the etching rate of the dielectric layer (first layer) 3.

(5) Next, the connecting sections 30 are removed by dry etching. First, resist is coated over the entire surface of the base substrate 1, and then the resist is patterned by a photolithography method, whereby a resist layer 90 that covers areas other than the connection sections 30 is formed, as shown in FIG. 7. A resist opening section 92 that opens in the resist is formed over the connection sections 30. The resist layer 90 can embed, for example, the cavity section 80 and the first opening section 44. Then, by using the resist layer 90 as a mask, the connection sections 30 are removed by dry etching. Then, the resist layer 90 is removed by ashing.

Through the steps described above, the connection sections 30 are removed such that the mechanical force of constraint of the oscillation sections 10 with respect to their free ends 14 is cancelled, and the oscillation sections 10 can sufficiently vibrate. Also, through the steps described above, the opening section (second opening section) 42 is formed, as shown in FIG. 1 and FIG. 2.

(6) By the process described above, the piezoelectric oscillator 100 in accordance with the present embodiment is formed, as shown in FIG. 1 and FIG. 2.

3. The piezoelectric oscillator 100 in accordance with the present embodiment includes the plurality of oscillator sections 200, wherein the oscillator sections 200a, 200b and 200c are equipped with the oscillation sections 10a, 10b and 10c that are different in length, respectively. Because the oscillation sections 10a, 10b and 10c have different lengths, the resonance frequency of the flexing vibration of each of the oscillation sections 200a, 200b and 200c is different from one another. Accordingly, by combining on/off operations of the oscillation sections 200a, 200b and 200c, signals with a variety of frequencies can be outputted from the single piezoelectric oscillator 100.

Also, by the piezoelectric oscillator 100 in accordance with the present embodiment, signals with a variety of frequencies can be outputted from the single piezoelectric oscillator 100. As a consequence, for example, when a plurality of piezoelectric oscillators 100 are manufactured, the same mask patterns for patterning oscillation sections 10 can be used without changing them. In other words, according to the method for manufacturing piezoelectric oscillators 100 in accordance with the present embodiment, a plurality of piezoelectric oscillators 100 can be manufactured without using different mask patterns, and signals with different frequencies can be outputted from the piezoelectric oscillators 100.

Also, according to the method for manufacturing a piezoelectric oscillator 100 in accordance with the present embodiment, the oscillation section 10 is affixed to the supporting section 40 by the connecting section 3Q, in the step of forming the cavity section 80 by wet etching. For example, if wet etching is conducted in a state where the oscillation section 10 is not affixed, the oscillation section 10 may stick, at its lower surface on the side of the free end 14, to the bottom surface of the cavity section 80 (top surface of the substrate 2) or to the pattern on the left or right side of the oscillation section 10, and cannot be separated therefrom, in other words, a so-called sticking problem may occur. In contrast, according to the method for manufacturing the piezoelectric oscillator 100 in accordance with the present embodiment, the oscillation sections 10 are affixed to the supporting section 40 by the connection sections 30, and therefore the problem described above would not occur. As a result, the manufacturing yield of the piezoelectric oscillator 100 can be improved.

Also, according to the method for manufacturing the piezoelectric oscillator 100 in accordance with the present embodiment, by changing the length of the connection section 30 in X direction, the length of the oscillation section 10 can be changed. In other words, in the step of removing the connection section 30 by dry etching, the length of the resist opening section 92 in X direction may be changed, whereby the length of the oscillation section 10 can be freely changed. Accordingly, by the method for manufacturing the piezoelectric oscillator 100 in accordance with the present embodiment, a common process may be used up to the wet etching step for forming the cavity section 80, and by merely changing a resist pattern in the dry etching step to be conducted later, the oscillation section 10 in any optional length can be readily obtained.

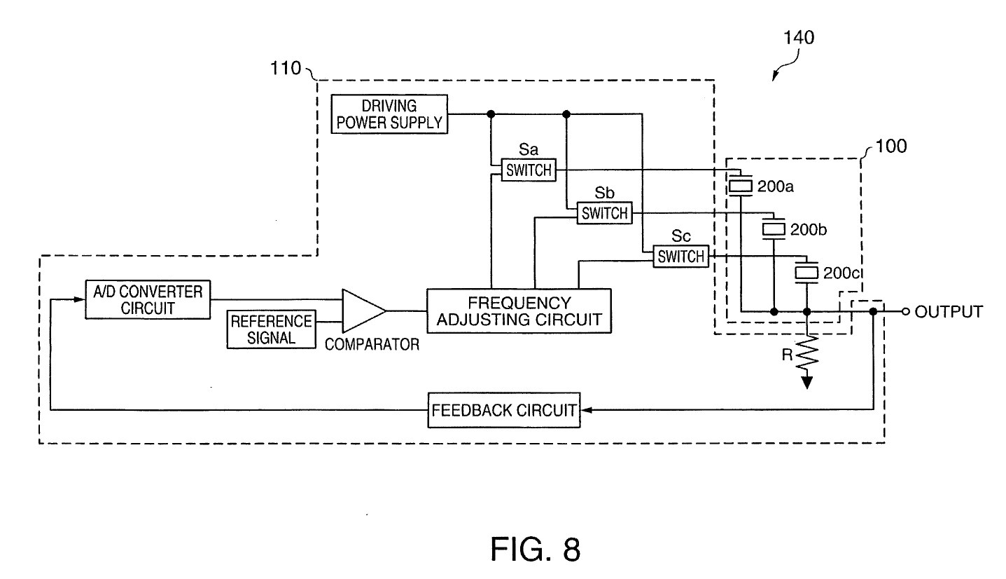

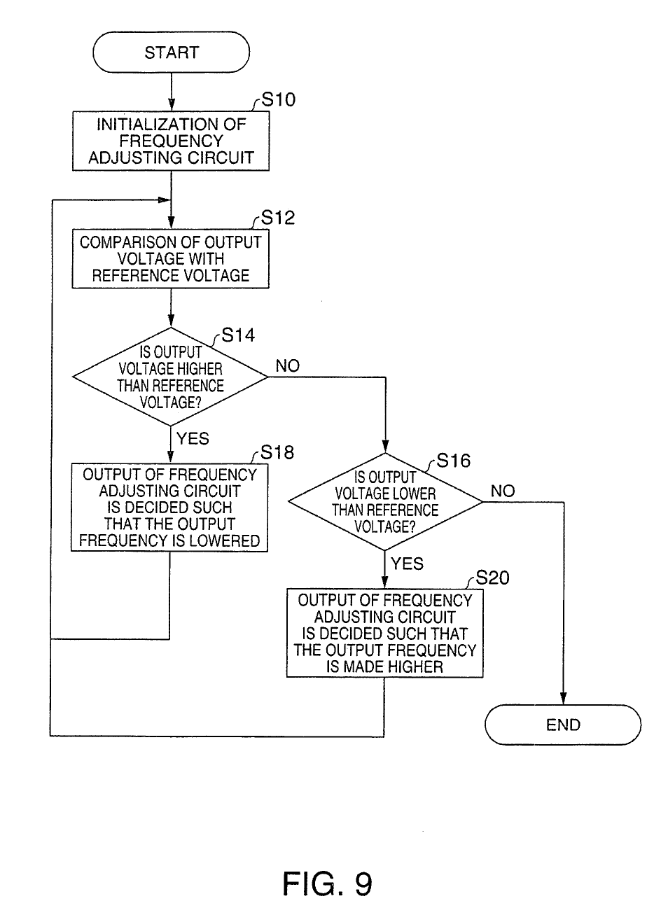

4. Next, a MEMS device 140 in accordance with an embodiment of the invention is described. FIG. 8 is a circuit diagram schematically showing the MEMS device 140 in accordance with the present embodiment, and FIG. 9 is a flow chart of execution of signal processing by the MEMS device 140 in accordance with the present embodiment.

The MEMS device 140 in accordance with the present embodiment includes, as shown in FIG. 8, the piezoelectric oscillator 100 in accordance with the present embodiment described above, and a control circuit 110 that feeds back an output of the piezoelectric oscillator 100 and controls the frequency of the output. The control circuit 110 may include, for example, a frequency adjusting circuit, switches, a driving power supply, a feedback circuit, an A/D converter circuit, and a comparator, as shown in FIG. 8. Also, the MEMS device 140 may have a peripheral circuit (not shown). The control circuit 110 and the peripheral circuit may be built in, for example, a semiconductor layer 4 (see FIG. 2).

Execution flow of signal processing by the MEMS device 140 in accordance with the present embodiment may be, for example, as follows (see FIG. 9).

First, the frequency adjusting circuit is initialized (step S10). As the frequency adjusting circuit, for example, an up/down counter may be used. The frequency adjusting circuit may be initialized by, for example, inputting an initial value in the up/down counter.

Next, an output voltage of the piezoelectric oscillator 100 and a reference voltage are compared (steps S12, S14, S16). The output voltage of the piezoelectric oscillator 100 may be inputted by, for example, the feedback circuit to the A/D converter circuit, converted to a digital value, and can be compared by the comparator with the voltage of the reference signal. It is noted that, instead of comparison of voltages, for example, impedances may be compared. Also, instead of comparison of digital values, analog values may be compared. In this case, the A/D converter circuit becomes unnecessary.

When, as a result of the comparison, the output voltage of the piezoelectric oscillator 100 is higher than the reference voltage, the output of the frequency adjusting circuit is decided such that the output frequency of the piezoelectric oscillator 100 is lowered (step S18). More specifically, on and off states of the switches Sa, Sb and Sc are decided such that the output frequency of the piezoelectric oscillator 100 is lowered. For example, when the switch Sa is turned on, the power is inputted from the driving power supply to the first oscillator section 200a, whereby the first oscillator section 200a is operated. Also, for example, when the switch Sb is turned on, the power is inputted from the driving power supply to the second oscillator section 200b, whereby the second oscillator section 200b is operated. Also, for example, when the switch Sc is turned on, the power is inputted from the driving power supply to the third oscillator section 200c, whereby the third oscillator section 200c is operated. As the switches Sa, Sb and Sc, for example, operation amplifiers, switching transistors or the like may be used.

More specifically, for example, for lowering the output frequency of the piezoelectric oscillator 100 in a state where the second oscillator section 200b alone is operating, for example, the switch Sb may be turned off, and the switch Sa may be turned on, such that the first oscillator section 200a having a longer oscillation section 10 may be operated alone. It is noted that the frequency adjustment example described above is only an example, and the invention is not limited to such an example. For example, plural ones of the switches may be turned on such that plural ones of the oscillator sections 200 are concurrently operated. At least one of the switches Sa, Sb and Sc may be turned on.

When, as a result of the comparison, the output voltage of the piezoelectric oscillator 100 is lower than the reference voltage, the output of the frequency adjusting circuit is decided such that the output frequency of the piezoelectric oscillator 100 is made higher (step S20). More specifically, on and off states of the switches Sa, Sb and Sc are decided such that the output frequency of the piezoelectric oscillator 100 is increased.

More specifically, for example, for increasing the output frequency of the piezoelectric oscillator 100 in a state where the second oscillator section 200b alone is operating, for example, the switch Sb may be turned off, and the switch Sc may be turned on, such that the third oscillator section 200c having a shorter oscillation section 10 may be operated alone. It is noted that the frequency adjustment example described above is only an example, and the invention is not limited to such an example. For example, plural ones of the switches may be turned on such that plural ones of the oscillator sections 200 are concurrently operated. At least one of the switches Sa, Sb and Sc may be turned on.

After the output of the frequency adjusting circuit is decided such that the output frequency of the piezoelectric oscillator 100 is made lower (step S18), or after the output of the frequency adjusting circuit is decided such that the output frequency of the piezoelectric oscillator 100 is made higher (step S20), the process can return to step S12 where the output of the piezoelectric oscillator 100 and the reference voltage are compared.

When, as a result of comparison (step S12), the output voltage of the piezoelectric oscillator 100 and the reference voltage (step S12) are found to be equal to each other, the process ends, and the piezoelectric oscillator 100 can output a signal with a desired frequency. In other words, the reference voltage with a value corresponding to the desired frequency output is inputted in the comparator. Also, even when the output voltage of the piezoelectric oscillator 100 and the reference voltage are not equal to each other, the output frequency of the piezoelectric oscillator 100 can be adjusted closer to a desired frequency by the execution flow described above. Accordingly, when the output frequency of the piezoelectric oscillator 100 is adjusted closer to a desired frequency, the process may be ended. Also, the output frequency of the piezoelectric oscillator 100, after having been adjusted close to a desired frequency, may repeatedly become higher and lower near the desired frequency. Therefore, the piezoelectric oscillator 100 may be used in such a state without completing the execution flow. Even in this case, the piezoelectric oscillator 100 can output a signal with a frequency that is close to a desired frequency.

In a manner described above, the output of the piezoelectric oscillator 100 is fed back, and the frequency of the output can be controlled.

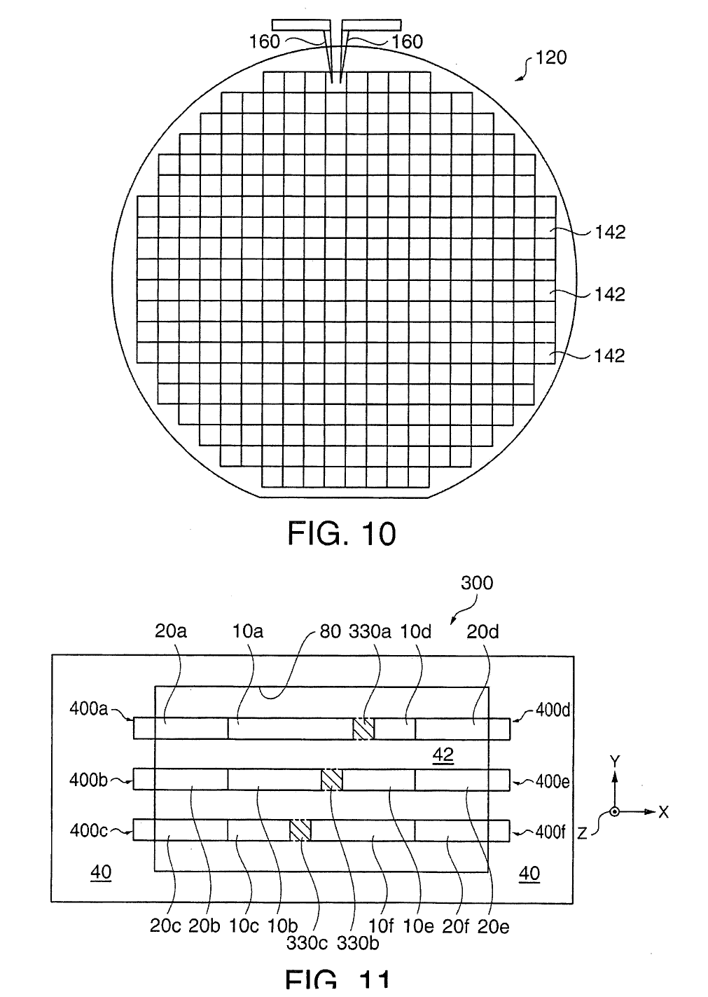

5. Next, an example of a method for manufacturing the MEMS device 140 in accordance with the present embodiment is described with reference to the accompanying drawings. FIG. 10 is a plan view schematically showing a manufacturing step in manufacturing the MEMS device 140 in accordance with the present embodiment.

(1) First, a MEMS wafer 120 having piezoelectric oscillators and control circuits in accordance with the present embodiment described above is fabricated. The MEMS wafer 120 is provided with, for example, a plurality of chip regions 142, each of which becomes a MEMS device in accordance with the present embodiment described above. The MEMS wafer 120 may be comprised of a single substrate and a plurality of piezoelectric oscillators and control circuits in accordance with the present embodiment formed in and on the substrate.

(2) Next, as shown in FIG. 10, for example, a probe 160 is brought in contact with each of the chip regions 142, and the piezoelectric oscillator and the control circuit on the MEMS wafer 120 are operated, wherein the frequency of a signal outputted from the piezoelectric oscillator (examination step) is measured.

(3) Next, for example, the MEMS wafer 120 is diced, thereby separating the MEMS wafer 120 into individual MEMS device chips.

(4) By the steps described above, the MEMS device 140 in accordance with the present embodiment is fabricated.

6. With the MEMS device 140 in accordance with the present embodiment, signals with a variety of frequencies can be outputted by changing a reference signal input.

Also, with the MEMS device 140 in accordance with the present embodiment, the input of a reference signal may be maintained constant, whereby the output frequency of the piezoelectric oscillator 100, which may vary depending on, for example, the patterning accuracy of the oscillation section 10 and the operation environment of the MEMS device 140, can be self-corrected.

Also, in the manufacturing method for manufacturing the MEMS device 140 in accordance with the present embodiment, the piezoelectric oscillator 100 and the control circuit 110 are operated in a wafer state, and the frequency of a signal outputted from the piezoelectric oscillator 100 is measured (examination step). As a result, a judgment can be made in the wafer state as to whether the piezoelectric oscillator 100 in each of the chip regions 140 can output a desired frequency.

Moreover, the MEMS device 140 in accordance with the present embodiment can output signals with a variety of frequencies, such that the defective rate in the examination step can be lowered, compared to devices that can output, for example, only a single frequency. Accordingly, by the method for manufacturing the MEMS device 140 in accordance with the present embodiment, the manufacturing yield can be improved through operating the piezoelectric oscillators 100 and the control circuits 110 in the examination step.

7. Modified examples of a piezoelectric oscillator and a method for manufacturing the same in accordance with the present embodiment are described. Features different from those of the piezoelectric oscillator 100 and its manufacturing method described above (hereafter referred to as an “example of piezoelectric oscillator 100”) are described, and description of the same features is omitted.

(1) First, a first modified example is described.

In the above-described example of piezoelectric oscillator 100, first, the semiconductor layer 4 of the base substrate 1 is patterned in a desired configuration, thereby forming the oscillation section 10 and the connecting section 30 (see FIG. 4 and FIG. 5), and then the connection section 30 is removed (see FIG. 7). However, for example, the semiconductor layer 4 may be patterned without forming the connection section 30. By this, the step of removing the connection section 30 becomes unnecessary.

(2) Next, a second modified example is described. FIG. 11 is a plan view schematically showing a piezoelectric oscillator 300 in accordance with the present modified example.

The piezoelectric oscillator 300 in accordance with the present modified example has a plurality of oscillator sections 400, wherein at least portions of the plural oscillation sections 10 are disposed with their free ends opposing to one another. In the illustrated example, the piezoelectric oscillator 300 has six oscillator sections 400a, 400b, 400c 400d, 400e and 400f. Furthermore, the first oscillation section 10a and the fourth oscillation section 10d are disposed with their free ends being opposite to each other, the second oscillation section 10b and the fifth oscillation section 10e are disposed with their free ends being opposite to each other, and the third oscillation section 10c and the sixth oscillation section 10f are disposed with their free ends being opposite to each other. In the present modified (example, at least two of the regions 330 between the opposing free ends may have the same area in a plan view. In the illustrated example, three of the regions 330a, 330b and 330c (i.e., all of them) between the opposing free ends have the same area in a plan view. In the illustrated embodiment, each of the regions 330a, 330b and 330c between the opposing free ends has a rectangular plane configuration.

Also, in the method for manufacturing the piezoelectric oscillator 300 in accordance with the present modified example, connection sections (hereafter appended with reference numbers 330a, 330b and 330c) may be provided at the regions 330a, 330b and 330c between the opposing free ends. The connection sections 330a, 330b and 330c can make the opposing oscillation sections 10 to be continuous, respectively. In the present modified example, at least two of the connection sections 330 may be formed to have the same area as viewed in a plan view. In the illustrated example, three of the connection sections 330a, 330b and 330c (i.e., all of them) have the same area as viewed in a plan view.

According to the piezoelectric oscillator 300 in accordance with the present modified example, more oscillation sections 10 having different lengths can be formed in the same device area as viewed in a plan view, compared to the example of piezoelectric oscillator 100. Accordingly, signals with more frequencies can be outputted from a single piezoelectric oscillator 300. Also, for example, when the piezoelectric oscillator 300 in accordance with the present modified example is applied to the MEMS device 140 described above, the accuracy of frequency to be outputted can be improved.

Also, according to the method for manufacturing the piezoelectric oscillator 300 in accordance with the present modified example, the area of the connection section 330 in a plan view can be made smaller, compared to the example of piezoelectric oscillator 100. By this, damage to the piezoelectric oscillator 300 that may be caused by etching in the step of removing the connection section 300 can be reduced.

Also, according to the method for manufacturing the piezoelectric oscillator 300 in accordance with the present modified example, at least two of the connection sections 330 can be made to have the same area in a plan view, such that differences in etching can be suppressed in the removal of the connection sections 330 having the same area.

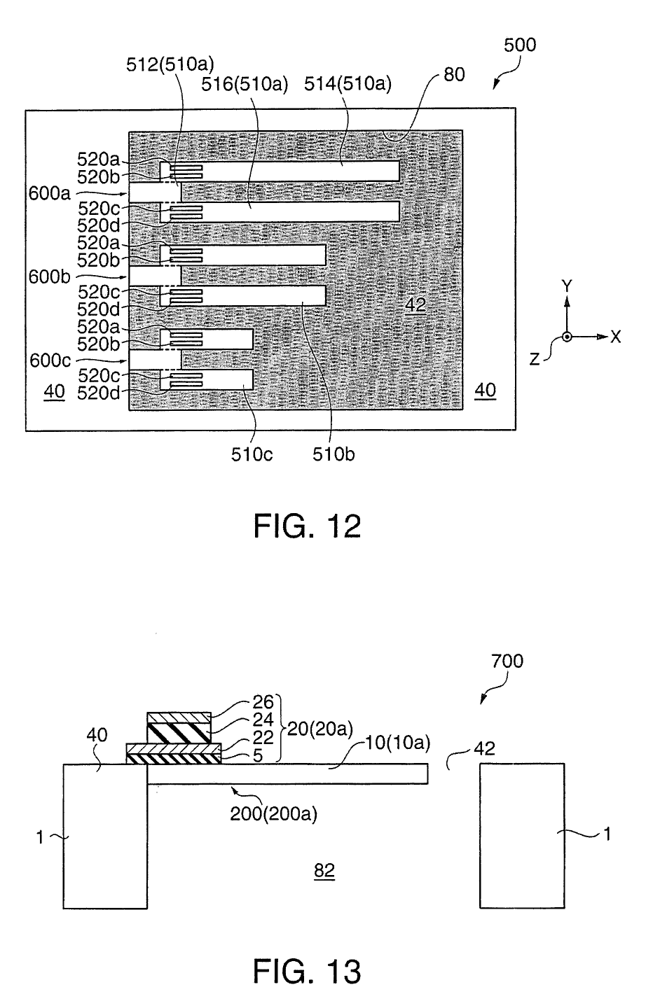

(3) Next, a third modified example is described. FIG. 12 is a plan view schematically showing a piezoelectric oscillator 500 in accordance with the present modified example.

In the present modified example, each of the oscillation sections 510a, 510b and 510c of the respective oscillator sections 600a, 600b and 600cis composed of a base section 512 and two beam sections 514 and 516 having the base section 512 as their base end, which are in a tuning fork shape. The base section 512 connects the supporting section 40 to the beam sections 514 and 516. The base section 512 has a plane configuration that is rectangular, for example as shown in FIG. 12. The two beam sections 514 and 516 are disposed in the lengthwise direction (X direction) in parallel with each other, spaced at a predetermined gap (the width of the base section 512). The beam sections 514 and 516 each have a plane configuration that is rectangular, for example, as shown in FIG. 12.

Driving sections 520 in a pair is provided on each of the beam sections 514 and 516. On the first beam section 514 is provided a first driving section 520a and a second driving section 520b formed along the lengthwise direction of the first beam section 514 in parallel with each other. Similarly, on the second beam section 516 is provided a third driving section 520c and a fourth driving section 520d formed along the lengthwise direction of the second beam section 516 in parallel with each other. The first driving section 520a disposed on the outer side of the first beam section 514 and the fourth driving section 520d disposed on the outer side of the second beam section 516 are electrically connected together by a wiring (not shown). The second driving section 520b disposed on the inner side of the first beam section 514 and the third driving section 520d disposed on the inner side of the second beam section 516 are electrically connected together by a wiring (not shown).

According to the present modified example, the driving sections 520 are provided in a manner to be separated from the outer periphery of the cavity section 80, such that the driving sections 520 can be prevented from impacts of side etching that may be caused by wet etching in the step of forming the cavity section 80.

(4) Next, a fourth modified example is described. FIG. 13 is a cross-sectional view schematically showing a piezoelectric oscillator 700 in accordance with the present modified example.

The piezoelectric oscillator 700 in accordance with the present modified example may have, as shown in FIG. 13, an opening section 82 that is formed by, for example, removing a portion of the base substrate 1 from its back surface side. The opening section 82 may be provided, for example, in the same position as the cavity section 80 in the example of piezoelectric oscillator 100, as viewed in a plan view. The opening section 82 is, for example, a portion of the base substrate 1, and may be formed by removing a portion of the base substrate up to the lower surface of the oscillation section 101 from the back surface of the base substrate 1.

(6) It is noted that the modified examples described above are only example, and the invention is not limited to these modified examples. For example, the modified examples may be appropriately combined. For example, the first modified example and the second modified example may be combined together.

8. The embodiments of the invention are described above in detail. However, a person having an ordinary skill in the art should readily understand that many modifications can be made without departing in substance from the novel matter and effect of the invention. Accordingly, those modified examples are also deemed included in the scope of the invention.

What is claimed is:

1. A piezoelectric oscillator comprising:
a base substrate;
a frame-like supporting section formed from a portion of the base substrate; and
a plurality of oscillator sections,
wherein each of the oscillator sections includes an oscillation section that is formed from a portion of the base substrate, and has one end affixed to an inner side of the support section and another free end, and a driving section that generates flexing vibration at the oscillation section, and wherein the oscillation sections are different in length, and each of the driving sections has a first electrode formed above the base substrate, a piezoelectric layer formed above the first electrode, and a second electrode formed above the piezoelectric layer.

2. A piezoelectric oscillator according to claim 1, wherein each of the oscillation sections is formed from a single beam section, and the driving section in singularity is provided on the beam section.

3. A piezoelectric oscillator according to claim 1, wherein each of the oscillation sections has a tuning fork shape composed of a base section and two beam sections with the base section as a base end, and each of the beam sections is provided with a pair of the driving sections.

4. A piezoelectric oscillator according to claim 1, wherein the free ends of at least a portion of the plurality of oscillation sections are disposed opposite to each other.

5. A piezoelectric oscillator according to claim 4, wherein at least two areas in a plan view among regions between the opposing free ends are equal to each other.

6. A micro electro mechanical system (MEMS) device comprising the piezoelectric oscillator recited in claim 1, and a control circuit that feeds back an output of the piezoelectric oscillator and controls a frequency of the output.

7. A method for manufacturing a MEMS device, the method comprising the steps of:
forming a MEMS wafer having the piezoelectric oscillator set forth in claim 1 and a control circuit that feeds back an output of the piezoelectric oscillator and controls a frequency of the output; and
operating the piezoelectric oscillator and the control circuit on the MEMS wafer to measure a frequency of an output of the piezoelectric oscillator.

8. A method for manufacturing a piezoelectric oscillator comprising the steps of:
preparing a base substrate having a substrate, a first layer formed above the base substrate and a second layer formed above the first layer;
forming, above the base substrate, a driving section that generates flexing vibration of an oscillation section of each of a plurality of oscillator sections;
patterning the second layer to form a frame-like supporting section, the oscillation section having a base end at an inner side of the supporting section and another end provided so as not to contact the supporting section, a connecting section that connects the oscillation sections together, and an opening section that exposes the first layer;
removing a portion of the first layer exposed through the opening section by wet etching, thereby forming a cavity section at least below the oscillation section; and
removing the connecting section by dry etching after forming the cavity section,
wherein the step of forming the driving section includes the steps of forming a first electrode above the base substrate, forming a piezoelectric layer above the first electrode, and forming a second electrode above the piezoelectric layer, wherein the oscillation sections are formed in different lengths, free ends of at least a portion of the plurality of oscillation sections are disposed opposite to each other, the connection section is provided between the opposing free ends, and at least two of the connection sections are formed to have the same area in a plan view.
